(19) United States
(12) Patent Application Publication
(10) Pub. No.: US 2024/0110275 A1
(43) Pub. Date: Apr. 4, 2024

(54) METHOD OF PROVIDING A REACTION CHAMBER, REACTION CHAMBER AND LASER EVAPORATION SYSTEM

(71) Applicant: MAX-PLANCK-GESELLSCHAFT ZUR FÖRDERUNG DER WISSENSCHAFTEN E.V., München (DE)

(72) Inventors: Wolfgang BRAUN, Bietigheim-Bissingen (DE); Jochen MANNHART, Böblingen (DE); Johannes Arnoldus BOSCHKER, Stuttgart (DE)

(21) Appl. No.: 18/274,439

(22) PCT Filed: Feb. 18, 2021
(86) PCT No.: PCT/EP2021/053996

§ 371 Date: Jul. 26, 2023

(51) Int. Cl. C23C 14/28; C30B 23/06

(52) U.S. Cl. CPC C23C 14/28; C30B 23/066

(57) ABSTRACT

The present invention relates to a method of providing a reaction chamber (10) for a laser evaporation system (100), the reaction chamber (10) comprising at least one wall section (20) with an inner surface (22) facing a reaction volume (12) of the laser evaporation system (100). In addition, the present invention relates to a reaction chamber (10) for a laser evaporation system (100), the reaction chamber (10) comprising at least one wall section (20) with an inner surface (22) enclosing a reaction volume (12). Further, the present invention relates to a laser evaporation system (100) comprising a reaction chamber (10).

The present invention relates to a method of providing a reaction chamber for a laser evaporation system, the reaction chamber comprising at least one wall section with an inner surface facing a reaction volume of the laser evaporation system. In addition, the present invention relates to a reaction chamber for a laser evaporation system, the reaction chamber comprising at least one wall section with an inner surface enclosing a reaction volume. Further, the present invention relates to a laser evaporation system comprising a reaction chamber.

In laser evaporation systems, such as used for instance for thermal laser epitaxy (TLE) or similar applications, high intensity laser beams are directed into a reaction chamber. In these systems, laser beams are scattered and reflected off reflecting surfaces inside the reaction chamber, in particular on metal parts, often in unpredictable directions. As these reaction chambers normally consist of metal, in particular for instance stainless steel, and comprise smooth, often even polished, surfaces, said reflections commonly occur. The reflected laser beam remains rather well collimated and keeps its high intensity. Sensitive parts inside the vacuum chamber are hence in danger of being damaged by these reflected laser beams, in particular as reflections on curved surfaces can also lead to focusing the reflected laser beams.

Aforementioned reflections in unpredictable directions happen in particular in TLE, when the laser beam melts the source surface, and uneven evaporation or dynamical instabilities on the source surface reflect the laser beam in unwanted and unforeseen directions.

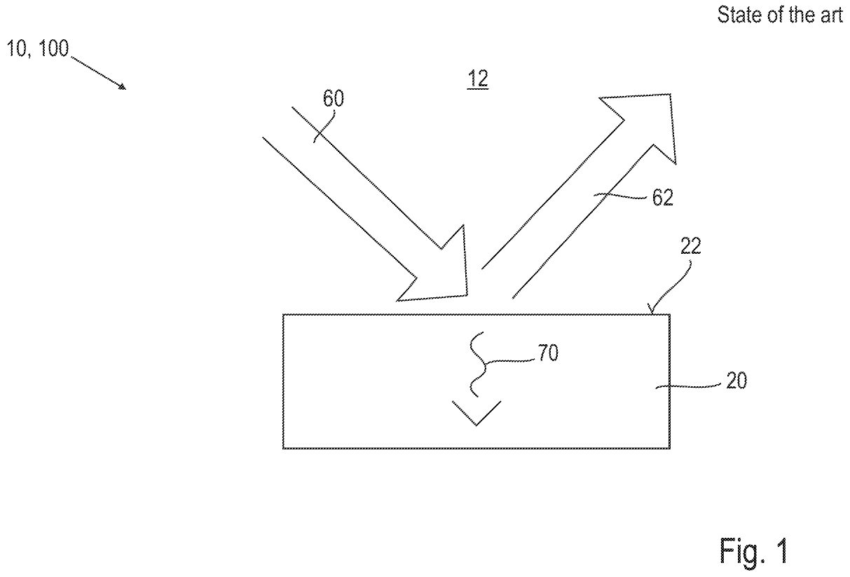

FIG. 1 schematically shows a laser beam 60 reflected into a reflected laser beam 62 on an inner surface 22 of a wall section 20. The wall section 20 forms part of a reaction chamber 10 of a laser evaporation system 100, and encloses a reaction volume 12. As in most of the cases the material used for the wall section 20 is metal, for instance stainless steel, and as further the inner surface is normally at least smooth if not even polished, the intensity of the reflected laser beam 62 is at least almost the same as the intensity of the impinging laser beam 60. In FIG. 1 this behavior is indicated by the essentially same width of the arrows representing the respective laser beams 60, 62. Only a small fraction of the impinging laser beam 60 is absorbed by the material of the wall section 20 as absorbed radiation 70. As further the wall section 20 and hence the inner surface 22 often comprises a curved shape, this high intensity of the reflected laser beam 62 can even be additionally focused at some point or region into a focal volume within the reaction chamber 10, causing the severe problems mentioned above.

In view of the above, it is an object of the present invention to provide an improved method of providing a reaction chamber, an improved reaction chamber and an improved laser evaporation system which do not have the aforementioned drawbacks of the state-of-the-art. In particular it is an object of the present invention to provide a method of providing a reaction chamber, a reaction chamber and a laser evaporation system which provide reduced internal reflection of the laser beam.

The aforementioned object is satisfied by the respective independent patent claims. In particular, this object is satisfied by a method of providing a reaction chamber according to claim 1, by a reaction chamber according to claim 27, a reaction chamber according to claim 29 and by a laser evaporation system according to claim 30. The dependent claims describe preferred embodiments of the invention. Details and advantages described with respect to a method of providing a reaction chamber according to the first aspect of the invention also refer to a reaction chamber according to the second and third aspect of the invention and to a laser evaporation system according to the fourth aspect of the invention, and vice versa.

According to the first aspect of the invention, the object is satisfied by a method of providing a reaction chamber fora laser evaporation system, the reaction chamber comprising at least one wall section with an inner surface facing a reaction volume of the laser evaporation system, the method comprising the steps of
a) Assembling the reaction chamber using the at least one wall section, and
b) Treating the at least one wall section for enhancing a dispersive reflectivity of the inner surface and/or for enhancing an ability for absorption of the inner surface.

In laser evaporation systems, a laser beam is directed onto a surface of a target in particular for evaporating, sublimating and/or sputtering material of the target. For providing a controlled reaction atmosphere for said reactions, the target is arranged within a reaction chamber, wherein the reaction chamber holds in its reaction volume a specific reaction atmosphere or wherein the reaction chamber is evacuated. A method according to the present invention can be used for providing such a reaction chamber fora laser evaporation system.

In particular, said reaction chamber provided by the method according to the present invention comprises at least one wall section with an inner surface, which faces the reaction volume of the laser evaporation system. During an operation of the laser evaporation system, this inner surface can be hit by the laser beam and a reflection of the laser beam can occur.

In step a) of the method according to the present invention the reaction chamber is assembled. In course of this assembling, the at least one wall section is used. Assembling the reaction chamber according to the present invention encompasses for instance mounting of the reaction chamber using several pieces including the at least one wall section, but also milling the reaction chamber from the solid and forming the at least one wall section while milling.

Adding flanges, holding structures and the like to the reaction chamber can also be done during this first step a) of the method according to the present invention, but are not necessarily included.

In summary, after step a) of the method according to the present invention, the reaction chamber is finished with respect to the reaction volume. In other words, after step a) of the method according to the present invention the reaction volume is essentially confined by a chamber wall, wherein the at least one wall section forms a part of said chamber wall.

In step b) of the method according to the present invention, the at least one wall section is specifically treated. Said treatment provides an enhancement of a dispersive reflectivity of the inner surface and/or of an ability for absorption of the inner surface. As pointed out in the following, both measures, individually and in combination, reduce the intensity of a laser beam reflected on the treated inner surface.

As mentioned above, laser light reflected on the inner surface can harm sensitive elements, for instance sensor elements, holding structures and/or actuator elements, arranged within the reaction volume. Even damaging the reaction chamber itself and/or parts like chamber windows and flanges, is possible. These dangers are in particular caused due to the high intensity of the laser beam used in laser evaporation systems and additionally the possibility of unintentionally focusing the reflected laser beam.

By enhancing a dispersive reflectivity, the angular spread of the reflected laser beam is enlarged. In other words, the reflected laser beam is less collimated and the reflection is spread over a large solid angle. Thereby drops the spatial intensity of the reflected laser beam and hence the danger of harming structures within the reaction chamber and/or of the reaction chamber itself is diminished.

Alternatively or additionally, also an ability for absorption of the inner surface can be enhanced. By enhancing this property of the inner surface, the fraction of the laser beam impinging onto the inner surface absorbed by the material of the at least one wall section is enlarged. In other words, the intensity of the reflected laser beam is diminished by the amount of energy absorbed by the material of the at least one wall section. As the intensity of the reflected laser beam is smaller, the danger of harming structures within the reaction chamber and/or of the reaction chamber itself is also lowered.

Preferably, the method according to the present invention can comprise that step b) is at least partly carried out before and/or simultaneously with respect to step a). In other words, the treatment of the at least one wall section can be carried out before and/or during the actual assembling of the reaction chamber. This can be in particular of advantage, if the at least one wall section is hard to reach for the particular treatment after assembling the reaction chamber. Further, providing several wall sections with different treatments can be provided easily, and hence tailoring the reaction chamber for the assumed stress during operation of the laser evaporation system can be provided.

In addition, the method according to the present invention can be characterized in that the treatment of the at least one wall section in step b) includes enhancing a roughness of the inner surface. As mentioned above, without treatment the inner surface of the at least one wall section is often smooth if not even polished. By enhancing a roughness of the inner surface an enhancement of a dispersive reflectivity can be easily provided. A rough inner surface reflects the impinging laser beam in a more diffuse way and in particular additional focusing effects for the reflected laser light can be avoided.

In particular, the method according to the present invention can be enhanced by enhancing the roughness of the inner surface via at least sand blasting and/or at least bead blasting of the inner surface. During a blasting process, small particles, for instance sand particles, preferably corundum (Al₂O₃), or glass particles, impact onto the blasted surface with high velocity. On impact, abrasion occurs and additionally the surface gets roughened. Using sand or corundum for the blasting process results in stronger abrasion than using glass. Hence, the most suitable particles used for the blasting process can be chosen with respect to the material of the at least one wall section and/or the roughness to be achieved by the blasting process.

In a further enhancement, the method according to the present invention can comprise that beads, in particular glass beads and/or corundum beads (Al₂O₃), of a size between 90 μm and 150 μm are used for the bead blasting. Beads, in particular glass beads or corundum beads, of a size between 90 μm and 150 μm used in blasting processes for the treatment of the inner surface of the at least one wall section are especially suitable for producing a sufficient roughness of the inner surface for ensuring dispersive reflection of impinging laser light. Please note that corundum grains are also corundum beads in the scope of the present invention.

Additionally or alternatively, the method according to the present invention can be characterized in that the treatment of the at least one wall section in step b) includes coating of the inner surface with an absorption layer. The absorption layer comprises a material, which provides an ability to absorb energy out of the impinging laser beam higher than the common material of the bulk of the at least one wall section. Therefore, in summary the ability for absorption of the inner surface, which comprises the bulk material of the at least one wall section coated and hence covered by the absorption layer, can be enhanced. Energy of the laser beam impinging on the inner surface is absorbed by the absorption layer and successively transferred into the bulk material of the at least one wall section. In summary, the intensity of the reflected laser beam can be diminished.

Preferably, the method according to the present invention can be enhanced by that the absorption layer is formed as a reaction product of a material of the at least one wall section with a material of a reactive fluid. In this preferred embodiment, the material of the at least one wall section provides the basic material for forming the absorption layer. For the actual coating, the inner surface of the at least one wall section is brought into contact with a reactive fluid. The respective materials of the at least one wall section and of the reactive fluid react with each other and form the absorption layer. As the at least one wall section provides its respective material throughout the inner surface, a complete bathing or exposure of the inner surface ensures likewise a complete coating of the inner surface with the absorption layer in an especially feasible and easy way. Further, as the absorption layer is formed as reaction product out of the material of the at least one wall section, the fixation between the absorption layer onto the remaining bulk material of the at least one wall section is exceedingly strong.

According to a further enhancement of the method according to the present invention, the reactive fluid contains oxygen and the absorption layer is an oxide of the material of the at least one wall section. Compared to pure materials, oxides of the respective material often comprise higher absorption values as the pure material. This especially holds true for metals, which are commonly used as materials for constructing reaction chambers. By using reactive fluids containing oxygen, the formation of an oxide as coating of the inner surface and hence as absorption layer can easily be provided.

Preferably, the method according to the present invention can be further enhanced by that the reactive fluid comprises molecular oxygen (O₂) and/or oxygen plasma and/or ozone (O₃). Molecular oxygen (O₂) and/or oxygen plasma and/or ozone (O₃) are all very reactive with respect of forming oxides with other materials, in particular metals. By providing molecular oxygen (O₂) and/or oxygen plasma and/or ozone (O₃) as part of the reactive fluid, the forming of an oxide as absorption layer can be enhanced, in particular compared to other reactive fluids, in which the oxygen is provided bonded in any type of molecule.

In an especially preferred enhancement of the method according to the present invention, the reactive fluid consists of molecular oxygen (O₂) and/or oxygen plasma and/or ozone (O₃). As mentioned above, molecular oxygen (O₂) and/or oxygen plasma and/or ozone (O₃) are all very reactive with respect of forming oxides with other materials, in particular metals. A reactive fluid consisting of molecular oxygen (O₂) and/or oxygen plasma and/or ozone (O₃) comprises no other components. Hence, the forming of an oxide as absorption layer can be further enhanced, in particular as any other reaction of the material of the at least wall section with other components of the reactive fluids is rendered impossible.
According to a further enhanced embodiment of the method according to the present invention, the reactive fluid comprises molecular oxygen (O₂) and ozone (O₃) at a volume ratio of 9:1. For special layers grown on substrates an oxidizing reaction atmosphere is used in laser evaporation systems, in particular when the layer to be grown is an oxide of the materials evaporated, sublimated and/or sputtered by the impinging laser beam. For said reaction atmospheres, a strongly oxidizing reaction atmosphere, in particular a gaseous fluid comprising or consisting of molecular oxygen (O₂) and ozone (O₃) at a ratio of 9:1 regarding the respective volume of the constituents, can be used. By using molecular oxygen (O₂) and ozone (O₃) at a ratio of 9:1 also as reactive fluid in the course of the method according to the present invention, the strongly oxidizing feature of this mixture can also be used to ensure the forming of an oxide as absorption layer as coating on the inner surface of the at least one wall section. Further, said volume ratio of 9:1 can be generated easily with standard ozone generators, in particular glow discharge ozone generators, using pure molecular oxygen (O₂) as primary material.

Preferably, the method according to the present invention can comprise that the coating of the inner surface is carried out after step a) and includes filling up the reaction volume with the reactive fluid. After completion of step a), the reaction chamber is fully assembled. In other words, the reaction volume is surrounded by a wall and can be tightened and sealed against the surrounding environment. This allows filling the reactive fluid into the reaction volume, whereby, due to the tightening and sealing of the reaction chamber, the reactive fluid stays contained within the reaction volume. This ensures on the one hand that the reactive fluid comes and stays in contact with the inner surface to be coated. On the other hand, leaking and/or discharging of the reactive fluid into the surrounding environment, and hence all accompanied harming effects of the reactive fluid for the surrounding environment, can be prohibited.

In particular, the method according to the present invention can be further enhanced by that the reaction volume is completely filled with the reactive fluid, in particular with a gaseous reactive fluid. By completely filling the reaction volume with the reactive fluid, bathing the inner surface of the at least one wall section to be coated can easily be ensured. Said completely filling is especially suitable with a gaseous reactive fluid. For instance, it is possible to firstly evacuate the reaction chamber, followed by filling the reaction chamber with the reactive fluid. A filling of the reaction chamber with only the pure reactive fluid can thereby be ensured.

Alternatively, the method according to the present invention can be characterized in that the reaction volume is filled partly, in particular less than 50%, preferably less than 10%, with the reaction fluid, in particular with a liquid reaction fluid, and preferably wherein the coating of the inner surface includes moving the reaction chamber to bath the entire inner surface with the reaction fluid. Filling the reaction volume with the reaction fluid only partly, in particular less than 50%, preferably less than 10%, reduces the amount of reactive fluid needed for the coating of the inner surface. This is suitable in particular for liquids as reaction fluids, as liquids are held gravitationally at the bottom part of the reaction chamber.

As mentioned above, the liquid reactive fluid tends to stay at the bottom of the reaction volume due to gravitation. This causes no problem if the inner surface to be coated is already bathed with the liquid reactive fluid after filling the reactive fluid into the reaction chamber. However, moving the reaction chamber can ensure that also other parts of the inner surface, in particular the complete inner surface of the reaction chamber is bathed with the reactive fluid. Hence the reaction of the reactive fluid with the bulk material of the at least one wall section for forming the oxide as absorption layer can be provided for all regions of the inner surface to be coated. In summary, with this particular embodiment of the method according to the present invention, coating the walls of the reaction volume is possible both only partly and completely, respectively.

In addition, the method according to the present invention can comprise that a target material is heated by a laser, in particular by a laser of the laser evaporation system, while the reaction volume is filled up with the reactive fluid. In addition to the forming of the coating as pure oxide of the material of the at least one wall section and the reactive fluid, also material of the respective heated target, evaporated, sublimated and/or sputtered by the laser, can be implemented into the absorption layer. Thereby the properties of the absorption layer can be selectively manipulated and hence a specific tailoring of the coating on the inner surface as absorption layer can be provided.

According to another preferred embodiment of the method according to the present invention, providing the reaction chamber in step a) includes choosing a material for the reaction wall comprising a heat conductivity >50 Wm⁻¹ K⁻¹, preferably >200 Wm⁻¹ K⁻¹. In other words, a material is chosen which comprises a good or even high heat conductivity, in particular compared with stainless steel, whose heat conductivity is about 15 to 40 Wm⁻¹ K⁻¹. In particular, aluminum and aluminum alloys (heat conductivity ˜75 to 237 Wm⁻¹ K⁻¹) and/or copper and copper alloys (heat conductivity ˜50 to 401 Wm⁻¹ K⁻¹) are exemplary materials to be used as material for the at least one wall section for the reaction chamber in this embodiment of the method according to the present invention. A material with high heat conductivity allows effectively spreading the energy absorbed from the impinging laser beam. High temperatures at the area where the laser beam impinges onto the inner surface, and the accompanying danger of harming the inner surface, can thereby be avoided or at least significantly lowered.

In particular, the method according to the present invention can be enhanced by that in step a) as material for the at least one wall section aluminum or an aluminum alloy, in particular the Al alloy 60826 or 6082T6 or ENAW-5083, is chosen. As mentioned above, aluminum or the aforementioned aluminum alloys comprise a heat conductivity starting from 75 up to 237 Wm⁻¹ K⁻¹. Hence, using aluminum or an aluminum alloy ensures the aforementioned advantages of effectively spreading the absorbed energy of the impinging laser beam.

Using aluminum or an aluminum alloy as material for the at least on wall section in this context has the additional advantage that to roughen the inner surface corundum beads are the most preferred choice for the blasting medium and as corundum is an oxide of aluminum. Using high-purity corundum, the blasting process therefore will not introduce additional elements to the inner surface of the reaction chamber. This allows a high-purity vacuum to be generated with the processed reaction chamber, and minimizes possible contaminations from the reaction chamber walls to be introduced into layers deposited in the reaction chamber, since only aluminum and oxygen are present at the inner surface. The aluminum oxide formed by exposing the inner surfaces of the reaction chamber to oxygen and/or oxygen plasma and/or ozone has the same chemical composition as the blasting medium, and is very hard, with a very high melting point, very low vapor pressure and low permeability to other molecules that could diffuse out of the metal chamber body.

Further, the method according to the present invention can comprise that the at least one wall section is chosen such that it comprises at least partially a thickness of >1 cm, preferably a thickness of >4 cm. In addition to the high heat conductivity provided by the material used for the at least one wall section, a thickness of >1 cm, preferably of >4 cm, ensures that the energy can spread over a large volume. Hence, said wall thickness is preferably provided at an assumed impinging position of the laser beam. Avoiding high temperatures at the location area where the laser beam impinges onto the inner surface, and the accompanying danger of harm to the inner surface, can thereby be provided more easily. In addition, such thick wall sections can for instance be provided by using aluminum or an aluminum alloy, as a density of aluminum and its alloys is significantly lower than for instance the density of stainless steel. Hence, by using aluminum or an aluminum alloy as material for the at least one wall section the weight of the reaction chamber stays manageable despite the enlarged wall thickness.

Preferably, the method according to the present invention is further enhanced by that the at least one wall section is chosen with a continuous thickness of >1 cm, preferably a continuous thickness of >4 cm. In other words, the at least one wall section comprises said enlarged thickness throughout its full extent. A volume for the absorbed energy to spread into can thereby be enlarged and hence the overall temperature rise caused by the absorbed energy be minimized.

Another embodiment of the method according to the present invention can comprise that the reaction chamber is provided with cooling means for an active cooling of the at least one wall section. As described above, the energy absorbed by the at least one wall section can lead to a rise of temperature, in particular at the actual location of the impinging of the laser beam onto the inner surface of the at least one wall section. An active cooling provided by cooling means can be used to transport this energy away, for instance towards a heat sink arbitrarily far away from the reaction chamber. Hence, the temperature of the inner surface can be lowered and any harm induced by the absorbed energy can be avoided. Preferably, the active cooling means comprise sensor elements for monitoring the cooling, for instance for a closed loop control of the active cooling provided by the cooling means. A controlled, in particular constant, temperature of the at least one wall section and/or its inner surface can thereby be provided.

In a first enhancement of the embodiment of the method according to the present invention described above, the method can comprise that the cooling means are provided before step a) and/or in step a) during the assembly of the reaction chamber. In other words, the cooling means can be assembled and/or manufactured independently of actually assembling of the reaction chamber as a whole. In particular, the at least one wall section can already be provided with the cooling means. For instance, different versions of the at least one wall section, respectively provided with different cooling means comprising individual cooling capabilities, can be provided, and accordingly be chosen for the specific requirements of the actual reactions chamber and/or laser evaporation system.

In an alternative or additional enhancement, the method according to the present invention can be characterized in that the cooling means are provided in step b) as treatment of the at least one wall section for enhancing an ability for absorption of the inner surface. In other words, in this embodiment the cooling means are assembled and/or manufactured after the assembly of the reaction chamber as a whole. In particular, it is even possible to firstly identify the locations of impact of the laser beam onto the inner surface of the at least one wall section and sequentially arrange the cooling means at said identified locations. This approach allows to specifically provide the cooling means at positions where they are needed most. A particular good cooling of the at least one wall section can thereby be provided.

Further, the method according to the present invention can be enhanced by that the cooling means comprises cooling ducts for a liquid and/or gaseous coolant. The cooling ducts can for instance be provided by pipes arranged at the outer surface and/or within of the at least one wall section. The coolant flows within the cooling ducts, thermal energy is transferred from the material of the at least one wall section into the coolant and thereby transported away from the at least one wall section. A particular easy cooling of the at least one wall section can thereby be provided.

Preferably, the method according to the present invention can further comprise that the cooling ducts are adapted for water as coolant. Water is a well-known coolant with an excellent ability to absorb energy due to its high heat capacity and high thermal conductivity. Hence, cooling the at least one wall section can be further improved by using water as coolant.

According to a preferred embodiment of the method according to the present invention, the cooling ducts are arranged within the at least one wall section of the reaction chamber. In this embodiment, a wall thickness of the at least one wall section is large enough for directly arranging the cooling ducts within the at least one wall section. An arrangement of the cooling ducts in the vicinity of the inner surface and hence of the impinging location of the laser beam can thereby be provided. Hence, the cooling provided by the coolant flowing through the cooling ducts can be improved further.

Please note that the aforementioned embodiment of the wall section provided with a, in particular continuous, thickness of >1 cm, preferably of >4 cm, is sufficient for arranging the cooling ducts within the at least one wall section. Wall sections with said thickness and nonetheless manageable weight can for instance be provided by using aluminum or an aluminum alloy as material for the at least one wall section.

In addition, the method according to the present invention can be further improved by that the cooling means are arranged at the at least one wall section at positions where laser radiation impinging on the inner surface of the wall section is expected during operation of the laser evaporation system. In other words, the cooling means are arranged exactly at the locations of the reaction chamber, where an application of energy during the operation of the laser evaporation system has the highest probability. Countering the energy deposited at these expected impact locations of laser beams onto the inner surface of the at least one wall section can thereby be provided in a most suitable way.

According to the second aspect of the invention, the object is satisfied by a reaction chamber for a laser evaporation system, the reaction chamber comprising at least one wall section with an inner surface enclosing a reaction volume. The reaction chamber according to the second aspect of the present invention is characterized in that the reaction chamber is provided by applying the method according to the first aspect of the present invention.

The reaction chamber according to the second aspect of the present invention can be used for the operation of a laser evaporation system. As the reaction chamber according to the second aspect of the present invention is provided by applying the method according to the first aspect of the present invention, all features and advantages described above with respect to a method according to the first aspect of the invention, can also be provided by the reaction chamber according to the second aspect of the invention provided by applying the method according to the first aspect of the invention.

In particular, the reaction chamber according to the second aspect of the present invention comprises at least one wall section with an inner surface facing the reaction volume of the reaction chamber. In course of applying the method according to the first aspect of the present invention for providing said reaction chamber, said at least one wall section was treated for enhancing a dispersive reflectivity of the inner surface and/or for enhancing an ability for absorption of the inner surface. Said treatment provides an enhancement of a dispersive reflectivity of the inner surface and/or of an ability for absorption of the inner surface. As pointed out above with respect to the method according to the first aspect of the present invention, both measures, individually and in combination, reduce the intensity of a laser beam reflected on the treated inner surface.

According to a preferred embodiment of the reaction chamber according to the second aspect of the present invention, the reaction chamber comprises two or more wall sections treated in step b) of the method according to the first aspect of the present invention, in particular wherein the reaction chamber at least essentially consists of wall sections treated in step b) of the method according to the first aspect of the present invention. In other words, an enlarged area of the surface of the reaction chamber encompassing the reaction volume, provided by the two or more wall sections, was treated for enhancing a dispersive reflectivity of the inner surface and/or for enhancing an ability for absorption of the inner surface. Preferably, said enlarged area forms at least essentially the complete surface of the reaction chamber encompassing the reaction volume, excluding only additional elements as for instance chamber windows. Thereby, a reduction of the intensity of a reflected laser beam can be increased and in particular maximized. As result, the danger of harming structures within the reaction chamber and/or the reaction chamber itself can be further diminished.

According to the third aspect of the invention, the object is satisfied by a reaction chamber for a laser evaporation system, optionally obtainable using a method according to the first aspect of the present invention, the reaction chamber comprising at least one wall section with an inner surface enclosing a reaction volume, the at least one wall section being formed of one of Aluminum, an Al alloy, Al alloy 60826, Al alloy 6082T6, and Al alloy ENAW-5083, the inner surface having an average surface roughness selected in the range of 1 μm to 500 μm and/or the inner surface being coated with an oxide layer, in particular comprising Al₂O₃, preferably consisting of Al₂O₃, with a thickness of the oxide layer being selected in the range of 10 nm to 10 μm.

The reaction chamber according to the third aspect of the present invention is intended to be used in a laser evaporation system. As described above, in such laser evaporation systems laser beams can impinge and be reflected on a surface encompassing a reaction volume, whereby the reflected laser beam may harm sensitive elements, for instance sensor elements, holding structures and/or actuator elements, arranged within the reaction volume. Even damaging the reaction chamber itself and/or parts like chamber windows and flanges, is possible. Said danger of harming is due to the still high intensity of the reflected laser beam, which can even be intensified by focusing effects.

For avoiding the aforementioned danger of harming, the reaction chamber according to the third aspect of the present invention can comprise one or both of the following specific constructional features.

In particular, the inner surface of at least one wall section of the reaction chamber according to the third aspect of the present invention can comprise an average surface roughness selected in the range of 1 μm to 500 μm. By providing a roughness of the inner surface in the range of 1 μm to 500 μm, an enhancement of a dispersive reflectivity can be easily provided.

If the average surface roughness gets lower, the resulting dispersive reflectivity gets less pronounced, and at an average surface roughness of less than 1 μm the effect can be neglected. This holds true especially for IR lasers, as the wavelength of the used laser beams also falls into this length scale.

On the other hand, if the average surface roughness is comparable to the beam diameter of the laser beam, the beam will not be split into several minor beams, but be reflected at each individual facet as a whole. In was found that this effect gets dominant for an average surface roughness larger than 500 μm.

In summary, a rough inner surface reflects the impinging laser beam in a more diffuse way. Hence, the intensity of the reflected laser beam is spread into a larger volume. Further, additional focusing effects for the reflected laser light can be avoided.

Preparing the rough surface of the at least one wall section using a blasting process with corundum beads, corundum being high-purity Al₂O₃, a cross-contamination of the inner surface with elements other than aluminum and oxygen can be minimized or avoided. This leads to an inner chamber surface with minimum outgassing rate and therefore exceptional vacuum performance.

In addition, or as an alternative, the inner surface of at least one wall section of the reaction chamber according to the third aspect of the present invention can be coated with an oxide layer, in particular comprising Al₂O₃, preferably consisting of Al₂O₃, with a thickness of the oxide layer being selected in the range of 10 nm to μm.

The oxide layer provides an ability to absorb energy out of the impinging laser beam higher than the common material of the at least one wall section, in particular for long-wavelength radiation beyond several μm wavelength. As the common material, as described below, comprises, preferably consists of, aluminum or an aluminum alloy, the oxide layer at least comprises or consists of Al₂O₃ The ability for absorption of the inner surface can be enhanced by coating the common material of the at least one wall section, which is hence covered by the oxide layer forming the coating. The low-end point of the values for the thickness of the oxide layer of 10 nm ensures the aforementioned enhancement in absorption, the high-end point of 10 μm prohibits an adverse effect on the aforementioned enhanced roughness of the inner surface.

In summary, energy of the laser beam impinging on the inner surface is absorbed by the oxide layer and successively transferred into the bulk material of the at least one wall section. Therefore, the intensity of the reflected laser beam can be diminished.

Generally, the at least one wall section is formed of one of Aluminum, Al alloy, Al alloy 60826, Al alloy 6082T6, and Al alloy ENAW-5083. Aluminum or the aforementioned aluminum alloys comprise a heat conductivity starting from 75 up to 237 Wm⁻¹ K⁻¹. A material with high heat conductivity allows spreading the energy absorbed from the impinging laser beam over a large volume of the at least one wall section in a fast, efficient and effective way. High temperatures at the location area where the laser beam impinges onto the inner surface, and the accompanying danger of harm to the inner surface, can thereby be avoided or at least significantly be lowered.

In addition, using aluminum or an aluminum alloy for forming the at least one wall section allows to provide a wall thickness of >1 cm, in particular of >4 cm. Such thick walls provide for instance a larger volume for energy absorbed from the impinging laser light. In addition, cooling ducts of cooling means can be arranged within the thick walls, preferably in the vicinity of the inner surface and hence of the impinging location of the laser beam. An especially good cooling can thereby be provided.

According to the fourth aspect of the invention, the object is satisfied by a laser evaporation system comprising a reaction chamber constructed according to the second or third aspect of the present invention. As the reaction chamber is constructed according to the second or third aspect of the present invention, all features and advantages described above with respect said reaction chamber according to the second or third aspect of the invention, can also be provided by the laser evaporation system according to the fourth aspect of the invention.

The present invention is further described hereinafter with reference to illustrated embodiments shown in the accompanying drawings. There is shown:

FIG. 1 A laser evaporation system according to the state of the art,

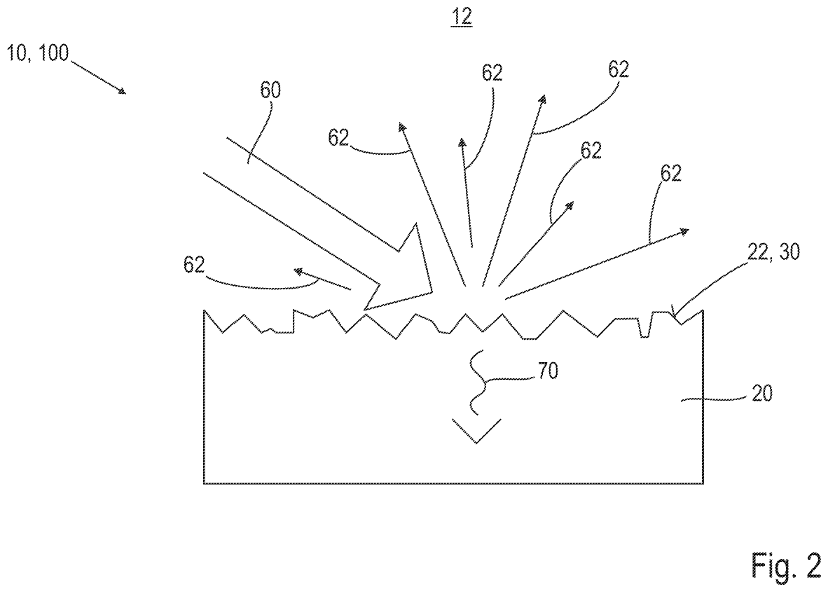

FIG. 2 A wall section with enhanced surface roughness of a laser evaporation system according to the invention,

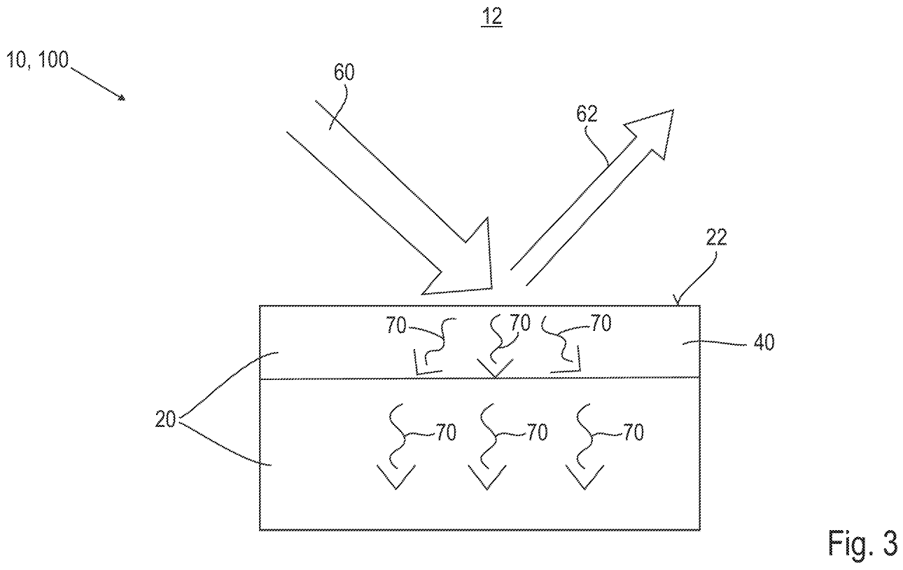

FIG. 3 A wall section with an absorption layer of a laser evaporation system according to the invention,

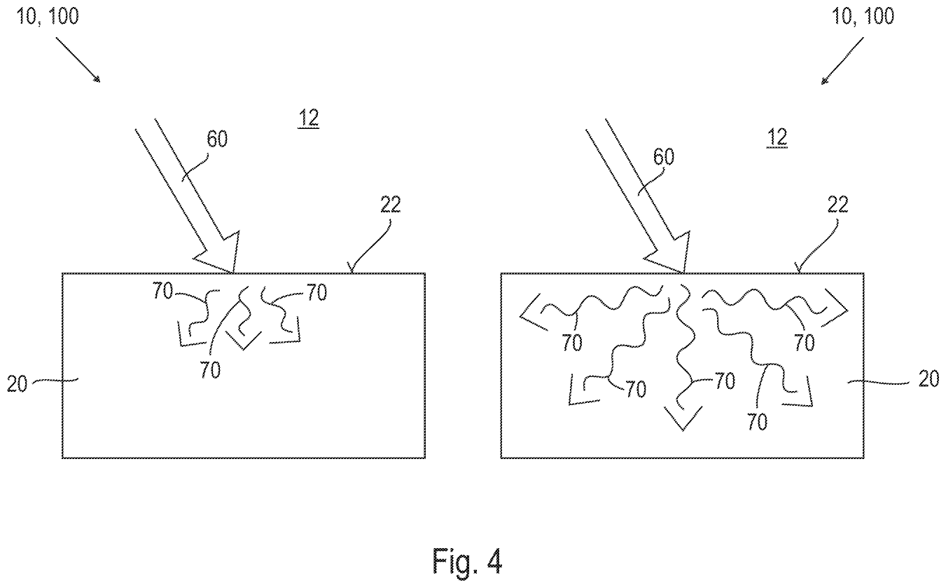

FIG. 4 Two wall sections with different thermal conductivity of a laser evaporation system according to the invention,

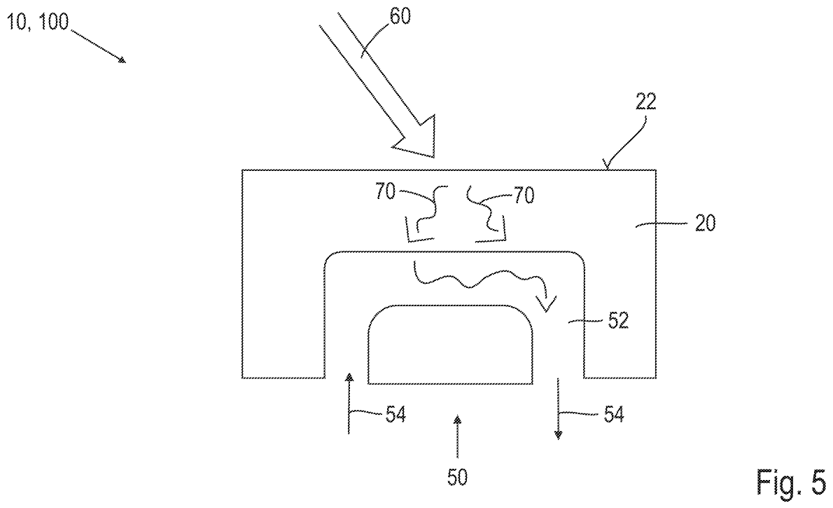

FIG. 5 A wall section with cooling means of a laser evaporation system according to the invention, and

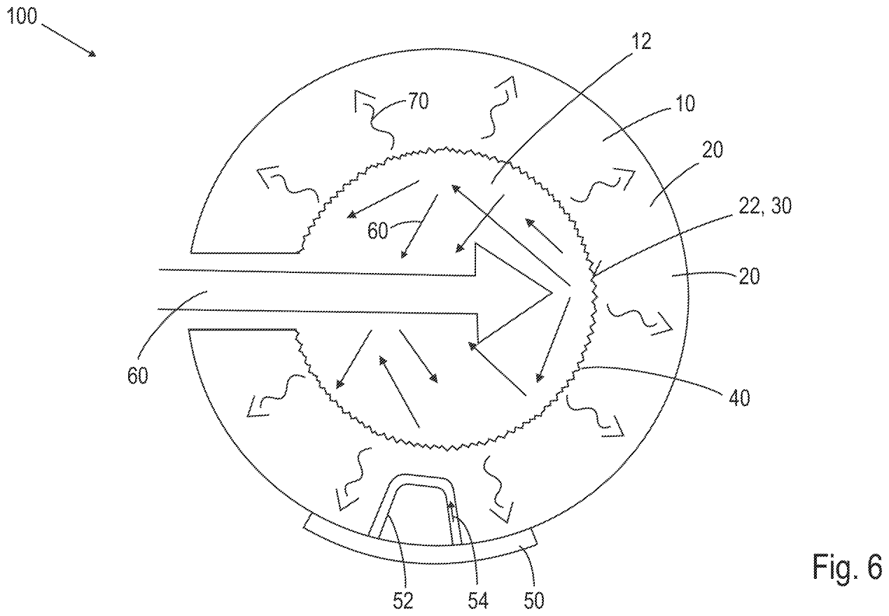

FIG. 6 A laser evaporation system according to the invention.

FIG. 2 schematically shows a laser beam 60 reflected into several reflected laser beams 62 on an inner surface 22 of a wall section 20. The wall section 20 forms part of a reaction chamber 10 according to the present invention of a laser evaporation system 100 according to the present invention, and encloses a reaction volume 12. In contrast to the situation shown in FIG. 1, the inner surface 22 was treated in course of the method according to the present invention. In particular, in step b) of said method according to the present invention, a roughness 30 of the inner surface 22 was increased.

Said treatment of the inner surface 22 can for instance comprise sand blasting and/or bead blasting the inner surface 22, in particular with beads, for instance corundum beads and/or glass beads, of a size between 90 μm and 150 μm. By this, an average surface roughness 30 selected in the range of 1 μm to 500 μm can be provided.

As clearly visible in FIG. 2, a dispersive reflection of the impinging laser beam 60, depicted by the plurality of smaller arrows representing the reflected laser beams 62 and emerging in arbitrary directions, can be enhanced by providing an enlarged roughness 30 of the inner surface 22. Only a small fraction of the impinging laser beam 60 is absorbed by the wall section 20 as absorbed radiation 70.

By enhancing a dispersive reflectivity, the angular spread of the reflected laser beam 62 is enlarged. In other words, the reflected laser beam 62 is less collimated and the reflection is spread over a large solid angle within the reaction volume 12. Thereby the spatial intensity of the reflected laser beam 62 drops and hence the danger of harming structures of the laser evaporation system 100 within the reaction chamber 10 and/or the reaction chamber 10 itself can be diminished.

In FIG. 3, the result of an alternative or additional treatment of the inner surface 22 of the at least one wall section 20 in course of step b) of the method according to the present invention is depicted. Again, the wall section forms a part of a reaction chamber 10 according to the present invention of a laser evaporation system 100 according to the present invention.

Here, the inner surface 22 is coated with an absorption layer 40. By this, a larger fraction of the energy of the impinging laser beam 60 is absorbed by the wall section 20 as absorbed radiation 70, and hence the intensity of the reflected laser beam 62 is diminished, as indicated by the smaller arrow illustrating the reflected laser beam 62 in FIG. 3.

Preferably, the absorption layer 40 is formed as reaction product of a reactive fluid and the bulk material of the wall section 20. Preferably, the reaction fluid contains oxygen and the reaction product is an oxide. This can easily be ensured by using a reactive fluid comprising, in particular consisting of, molecular oxygen (O₂) and/or ozone (O₃), preferably at a volume ratio of 9:1.

For the forming of the absorption layer, a pre-assembled reaction chamber 10 can be filled with the reactive fluid. Depending of the state of the reactive fluid, liquid or gaseous, the filling can be complete or only partially, for instance less than 50% or less than 10%, whereby only partially filling the reaction chamber 10 often needs additional moving the reaction chamber 10 for ensuring completely bathing the inner surface 22 of the wall section 20 with the reactive fluid. A further tailoring of the absorption layer 40 can be provided by additionally heating a dummy target with a laser beam while the reaction chamber 10 is filled with the reactive fluid. The absorbed radiation 70 is spread into the bulk material of the wall section 20, illustrated by the wiggly arrows 70 within the absorption layer 40 and the wall section 20. To spread the absorbed radiation 70 in a most efficient way, a material with a high thermal conductivity can be chosen for the wall section, see also FIG. 4. Such a material is for instance aluminum or an aluminum alloy. In this case, the absorption layer 40 is an oxide of aluminum, in particular Al₂O₃. As thickness of the oxide layer, a range of 10 nm to 10 μm has been found to be advantageous.

The influence of the thermal conductivity of the material used for the wall section 20 is depicted in FIG. 4. In the left figure, a wall section 20 with smaller thermal conductivity, in the right figure with larger thermal conductivity is shown. It is clearly visible that with smaller thermal conductivity the energy of the absorbed radiation 70 locally stays at the impinging location of the laser beam 60 and hence may locally lead to a severe temperature rise. This can even harm the wall section 20 itself. On the other hand, a high thermal conductivity, as for instance comprised by aluminum or an aluminum alloy with thermal conductivities up to >200 Wm⁻¹ K⁻¹, helps spreading the energy of the absorbed radiation 70 over a larger volume within the wall section 20 and hence the danger of harming the reaction chamber 10 and/or its components is diminished.

Another possibility for lowering the thermal stress in the bulk of the wall section 20 induced by the absorption of parts of the impinging laser beam 60, namely to provide cooling means 50, is shown in FIG. 5. These cooling means 50 preferably comprise a liquid and/or gaseous coolant 54, in particular water, which flows in cooling ducts 52. Absorbed radiation 70 propagates in the bulk of the wall section 20 and is again absorbed and subsequently carried away by the coolant 54 in the cooling ducts 52. These cooling means 50 can be arranged in the respective wall sections 20 already before assembling the reaction chamber 10, but also during the assembling or even after the assembling.

If the wall thickness of the wall section 20 is large enough, the cooling ducts 52 can be arranged within the wall section 20, in particular in vicinity of locations, at which an impinging laser beam 60 is expected during the operation of the laser evaporation system 100. In particular by using aluminum or an aluminum alloy as material for the wall section 20, a sufficient wall thickness of >1 cm or even >4 cm can easily be provided with still keeping up manageable weight of the reaction chamber 10.

Preferentially, instead of the U shape shown in FIG. 5, the cooling ducts 52 may form a V shape, consisting of two straight bores at an angle to each other and to the surface of the at least one wall section 20. Such a configuration is particularly easy to manufacture, as only two short, straight holes need to be bored, meeting at their bottom ends. In addition, the large-angle reflection of the coolant 54 at the tip of this v-shaped cooling duct 52 creates a turbulent flow in this region, with a correspondingly thin laminar layer near the coolant-metal interface, thereby enhancing the heat transfer. A V-shaped cooling duct 52 also allows a particularly easy application of localized cooling at the tip of this V shape close to regions of the at least one wall section 20 of the reaction chamber 10 with high impinging laser power density.

FIG. 6 schematically shows a laser evaporation system 100 according to the present invention, in particular its reaction chamber 10 according to the present invention, and a laser beam 60 fed into the reaction chamber 10. The reaction chamber 10 consists of several wall sections 20, wherein two of the wall sections 20 are depicted. The wall sections 20 consist of aluminum and comprise a wall thickness >4 cm.

The inner surface 22 of both wall sections 20 is coated with an absorption layer 40, in particular with the oxide Al₂O₃, with a thickness of the absorption layer 40 between 10 nm to 10 μm. Further, the inner surface 22 has an enhanced average surface roughness 30, in particular between 1 μm to 500 μm.

In one of the wall sections 20, exemplary cooling means 50 are depicted, in particular comprising a cooling duct 52 for the flow of a liquid and/or gaseous coolant 54. However, such cooling means 50 can be arranged throughout the reaction chamber 10 also at other locations.

As a result of the measures described above, the impinging laser beam 60 is only diffusely reflected into a plurality of reflected laser beams 62, each of them of lower intensity. Further, also an enlarged fraction of the impinging laser beam 60 is absorbed, in particular by the absorption layer 40 The absorbed radiation 70 is spread within the bulk of the wall sections 20 due to the high thermal conductivity of aluminum, and finally carried away by the coolant 54 of the cooling means 50.

In summary, in a laser evaporation system 100 according to the present invention, comprising a reaction chamber 10 according to the present invention which is provided by a method according to the present invention, the danger of harming structures within the reaction chamber 10 and/or the reaction chamber 10 itself due to an impact of high intensity laser beams 60 is diminished.

### REFERENCES

10 Reaction chamber
12 Reaction volume
20 Wall section
22 Inner surface
30 Roughness
40 Absorption layer
50 Cooling means
52 Cooling duct
54 Coolant
60 Laser beam
62 Reflected laser beam
70 Absorbed radiation
100 Laser evaporation system

1-30. (canceled)

31. A method of providing a reaction chamber for a laser evaporation system, the reaction chamber comprising at least one wall section with an inner surface facing a reaction volume of the laser evaporation system, the method comprising the steps of
a) Assembling the reaction chamber using the at least one wall section, and
b) Treating the at least one wall section for enhancing a dispersive reflectivity of the inner surface and/or for enhancing an ability for absorption of the inner surface.

32. The method according to claim 31,
wherein step b) is at least partly carried out before and/or simultaneously with respect to step a).

33. The method according to claim 31,
wherein the treatment of the at least one wall section in step b) includes enhancing a roughness of the inner surface.

34. The method according to claim 33,
wherein the enhancing of the roughness of the inner surface includes sand blasting and/or bead blasting of the inner surface.

35. The method according to claim 34,
wherein beads, in particular glass beads and/or corundum beads, of a size between 90 μm and 150 μm are used for the bead blasting.

36. The method according to claim 31,
wherein the treatment of the at least one wall section in step b) includes coating of the inner surface with an absorption layer.

37. The method according to claim 36,
wherein the absorption layer is formed as a reaction product of a material of the at least one wall section with a material of a reactive fluid.

38. The method according to claim 37,
wherein the reactive fluid contains oxygen and the absorption layer is an oxide of the material of the at least one wall section.

39. The method according to claim 38,
wherein the reactive fluid comprises molecular oxygen and/or oxygen plasma and/or ozone.

40. The method according to claim 39,
wherein the reactive fluid consists of molecular oxygen and/or oxygen plasma and/or ozone.

41. The method according to claim 39,
wherein the reactive fluid comprises molecular oxygen and ozone at a volume ratio of 9:1.

42. The method according to claim 37,
wherein the coating of the inner surface is carried out after step a) and includes filling up the reaction volume with the reactive fluid.

43. The method according to claim 42,
wherein the reaction volume is completely filled with the reactive fluid.

44. The method according to claim 42,
wherein the reaction volume is filled partly with the reaction fluid.

45. The method according to claim 42,
wherein a target material is heated by a laser while the reaction volume is filled up with the reactive fluid.

46. The method according to claim 31,
wherein providing the reaction chamber in step a) includes choosing a material for the reaction wall comprising a heat conductivity >50 Wm⁻¹K⁻¹.

47. The method according to claim 46,
wherein in step a) as material for the at least one wall section aluminum or an aluminum alloy is chosen.

48. The method according to claim 46,
wherein the at least one wall section is chosen such that it comprises at least partially a thickness of >1 cm.

49. The method according to claim 48,
wherein the at least one wall section is chosen with a continuous thickness of >1 cm.

50. The method according to claim 31,
wherein the reaction chamber is provided with cooling means for an active cooling of the at least one wall section.

51. The method according to claim 50,
wherein the cooling means are provided before step a) and/or in step a) during the assembly of the reaction chamber.

52. The method according to claim 50,
wherein the cooling means are provided in step b) as treatment of the at least one wall section for enhancing an ability for absorption of the inner surface.

53. The method according to claim 50,
wherein the cooling means comprises cooling ducts for a liquid and/or gaseous coolant.

54. The method according to claim 53,
wherein the cooling ducts are adapted for water as coolant.

55. The method according to claim 53,
wherein the cooling ducts are arranged within the at least one wall section of the reaction chamber.

56. The method according to claim 50,
wherein the cooling means are arranged at the at least one wall section at positions where laser radiation impinging on the inner surface of the wall section is expected during operation of the laser evaporation system.

57. A reaction chamber for a laser evaporation system, the reaction chamber comprising at least one wall section with an inner surface enclosing a reaction volume,
wherein the reaction chamber is provided by applying the method according to claim 31.

58. The reaction chamber according to claim 57,
wherein the reaction chamber comprises two or more wall sections treated for enhancing a dispersive reflectivity of the inner surface and/or for enhancing an ability for absorption of the inner surface.

59. A reaction chamber for a laser evaporation system, the reaction chamber comprising at least one wall section with an inner surface enclosing a reaction volume, the at least one wall section being formed of one of Aluminum, Al alloy, Al alloy 60826, Al alloy 6082T6, and Al alloy ENAW-5083, the inner surface having an average surface roughness selected in the range of 1 μm to 500 μm and/or the inner surface being coated with an oxide layer, with a thickness of the oxide layer being selected in the range of 10 nm to 10 μm.

60. A laser evaporation system comprising a reaction chamber constructed according to claim 59.
